(19) United States
(12) Patent Application Publication
(10) Pub. No.: US 2026/0317552 A1
(43) Pub. Date: Oct. 15, 2026

(54) ELECTRONIC DEVICE FOR IMMERSION COOLING WITH HYDROPHOBIC COATING ON FUNCTIONAL BODY

(71) Applicant: Infineon Technologies AG, Neubiberg (DE)

(72) Inventors: Stefan Pelties, Regensburg (DE); Michael Bauer, Nittendorf (DE)

(73) Assignee: Infineon Technologies AG, Neubiberg (DE)

(21) Appl. No.: 19/568,071

(22) Filed: Mar. 16, 2026

(30) Foreign Application Priority Data
Apr. 14, 2025 (DE) 10 2025 114 531.8

(51) Int. Cl. C09D 1/00; H05K 7/20

(52) U.S. Cl. CPC C09D 1/00; H05K 7/20236

(57) ABSTRACT

An electronic device for immersion cooling comprising at least one functional body being at least partially delimited by an encapsulant. A hydrophobic coating covers at least part of an exterior surface of the at least one functional body.

### CROSS-REFERENCE TO RELATED APPLICATION

This Utility Patent Application claims priority to German Patent Application No. 10 2025 114 531.8 filed Apr. 14, 2025, which is incorporated herein by reference.

### BACKGROUND

### Technical Field

Various embodiments relate generally to an electronic device, a method of manufacturing an electronic device for immersion cooling, and a method.

### Description of the Related Art

A conventional package may comprise an electronic component mounted on a chip carrier such as a leadframe, may be electrically connected by a bond wire extending from the chip to the chip carrier, and may be molded using a mold compound as an encapsulant.

During operation, such a package may be efficiently cooled by immersion cooling. However, degradation of a package may be an issue during immersion cooling. Similar issues may occur in other electronic devices.

### SUMMARY

There may be a need for enabling a proper cooling of an electronic device while simultaneously maintaining integrity of the electronic device.

According to an exemplary embodiment, an electronic device for immersion cooling is provided which comprises at least one functional body being at least partially delimited by an encapsulant, and a hydrophobic coating covering at least part of an exterior surface of the at least one functional body.

According to another exemplary embodiment, a method of manufacturing an electronic device for immersion cooling is provided, wherein the method comprises providing at least one functional body being at least partially delimited by an encapsulant, and covering at least part of an exterior surface of the at least one functional body by a hydrophobic coating.

According to still another exemplary embodiment, a method is provided, comprising providing an electronic device having the above mentioned features, and at least partially immersing the at least one functional body covered by the hydrophobic coating in an immersion cooling liquid.

According to an exemplary embodiment, an electronic device (for instance comprising a semiconductor package, for example mounted on a mounting board) may be specifically configured for immersion cooling. Thus, the electronic device may be structurally adapted so that it is compliant to be cooled by an immersion cooling liquid during operation of the electronic device for efficient heat removal. The electronic device may have one or more functional bodies which may be delimited only partially or entirely by an encapsulant (for example an epoxy mold compound). Advantageously, only part of or an entire exterior surface of the respective functional body may be covered or coated with a hydrophobic coating. Beneficially, the hydrophobic coverage of the encapsulated functional body may render the electronic device fully compatible with immersion cooling by inhibiting undesired direct interaction between the encapsulated functional body and an immersion liquid. Hence, the hydrophobic coating may provide a configuration of the at least partially encapsulated functional body which renders the electronic device particularly suitable for immersion cooling without the risk of undesired impact of immersion cooling liquid on the integrity of the functional body. For example, the hydrophobic coating may function as an intrinsic protecting layer suppressing, inhibiting or even eliminating an undesired direct chemical interaction in particular between encapsulant and cooling liquid. For instance, such an undesired interaction may involve the formation of free radicals which may lead to the generation, in turn, of organic acids, and the latter may deteriorate electronic device functionality. In a nutshell, an exemplary embodiment may provide an intrinsic device protection during immersion cooling.

### BRIEF DESCRIPTION OF THE DRAWINGS

The accompanying drawings, which are included to provide a further understanding of exemplary embodiments and constitute a part of the specification, illustrate exemplary embodiments.

In the drawings:

FIG. 1 illustrates an electronic device according to an exemplary embodiment.

FIG. 2 illustrates a hydrophobic coating of a functional body of an electronic device according to an exemplary embodiment.

FIG. 3 illustrates an electronic device according to another exemplary embodiment.

FIG. 4 illustrates an electronic device according to another exemplary embodiment.

FIG. 5 illustrates an electronic device according to another exemplary embodiment.

### DETAILED DESCRIPTION

There may be a need for enabling a proper cooling of an electronic device while simultaneously maintaining integrity of the electronic device.

According to an exemplary embodiment, an electronic device for immersion cooling is provided which comprises at least one functional body being at least partially delimited by an encapsulant, and a hydrophobic coating covering at least part of an exterior surface of the at least one functional body.

According to another exemplary embodiment, a method of manufacturing an electronic device for immersion cooling is provided, wherein the method comprises providing at least one functional body being at least partially delimited by an encapsulant, and covering at least part of an exterior surface of the at least one functional body by a hydrophobic coating.

According to still another exemplary embodiment, a method is provided, comprising providing an electronic device having the above mentioned features, and at least partially immersing the at least one functional body covered by the hydrophobic coating in an immersion cooling liquid.

According to an exemplary embodiment, an electronic device (for instance comprising a semiconductor package, for example mounted on a mounting board) may be specifically configured for immersion cooling. Thus, the electronic device may be structurally adapted so that it is compliant to be cooled by an immersion cooling liquid during operation of the electronic device for efficient heat removal. The electronic device may have one or more functional bodies which may be delimited only partially or entirely by an encapsulant (for example an epoxy mold compound). Advantageously, only part of or an entire exterior surface of the respective functional body may be covered or coated with a hydrophobic coating. Beneficially, the hydrophobic coverage of the encapsulated functional body may render the electronic device fully compatible with immersion cooling by inhibiting undesired direct interaction between the encapsulated functional body and an immersion liquid. Hence, the hydrophobic coating may provide a configuration of the at least partially encapsulated functional body which renders the electronic device particularly suitable for immersion cooling without the risk of undesired impact of immersion cooling liquid on the integrity of the functional body. For example, the hydrophobic coating may function as an intrinsic protecting layer suppressing, inhibiting or even eliminating an undesired direct chemical interaction in particular between encapsulant and cooling liquid. For instance, such an undesired interaction may involve the formation of free radicals which may lead to the generation, in turn, of organic acids, and the latter may deteriorate electronic device functionality. In a nutshell, an exemplary embodiment may provide an intrinsic device protection during immersion cooling.

### Description of Further Exemplary Embodiments

In the following, further exemplary embodiments of the electronic device and the methods will be explained.

In the context of the present application, the term “electronic device” may particularly denote a structure, body or arrangement of a plurality of structures and/or bodies fulfilling an electric or electronic function. In particular, such an electronic device may be configured for enabling a controlled flow of electric current and/or electric signals. For example, the electronic device comprises a package, in particular a semiconductor package comprising at least one encapsulated semiconductor component.

In the context of the present application, the term “immersion cooling” may particularly denote a system or mechanism of cooling an electronic device during operation by immersing the electronic device at least partially in an immersion cooling fluid, in particular in an immersion cooling liquid. Said immersion cooling fluid may be configured for dissipating heat from the electronic device generated during operation, and may thus cool the electronic device. Preferably, the immersion cooling fluid may be a dielectric cooling liquid. Immersion cooling may directly expose the electronic device to and promote interaction of the electronic device with dielectric cooling fluid for cooling purposes. Immersion cooling fluids may comprise dielectric fluids, such as single-phase or two-phase dielectric fluids, leveraging thermal capabilities to manage and dissipate heat generated by the electronic device. Immersion cooling may denote a form of liquid cooling in which the electronic device (for instance a server or part thereof) is immersed in a bath of non-conductive immersion cooling liquid. During electronic operation and cooling, heat may be transferred directly from the electronic device to the immersion cooling liquid.

This may be done without the need of additional cooling components, such as a heat sink.

In the context of the present application, the term “functional body” may in particular denote any constituent or member of the electronic device contributing to the electronic function of the electronic device. Such a functional body may for instance be an encapsulated electronic component, such as a semiconductor chip. Another example for a functional body is a for instance partially encapsulated carrier carrying an electronic component, for instance a leadframe-type carrier. Yet another example for a functional body is an electrically conductive connection structure, such as a clip or a bond wire, used for connecting an electronic component with a carrier.

In the context of the present application, the term “encapsulant” may particularly denote a material, structure or member surrounding at least part of an inner portion of a functional body (for instance one or more chips and optionally part of a carrier) to provide mechanical protection, and optionally electrical insulation and/or a contribution to heat removal during operation. In particular, said encapsulant may be predominantly or even entirely electrically insulating, for instance a mold compound. A mold compound may comprise a matrix of flowable and hardenable material and filler particles embedded therein. For instance, filler particles may be used to adjust the properties of the mold component, in particular to enhance thermal conductivity. As an alternative to a mold compound (for example on the basis of epoxy resin), the encapsulant may also be a potting compound (for instance on the basis of a silicone gel). In still another embodiment, the encapsulant may be a laminate of stacked layers (for instance comprising prepreg and/or resin sheets).

In the context of the present application, the term “hydrophobic coating” may particularly denote any physical body having hydrophobic or water-repellent properties.

For instance, such a body may be a planar or curved layer, a single-or multi-layer structure or a bulk body. In particular, a hydrophobic coating may have the chemical property to be seemingly repelled from water. A hydrophobic material may be non-polar and may thus prefer other neutral molecules and non-polar solvents. Water on the hydrophobic coating may exhibit a high contact angle. Examples of hydrophobic materials include alkanes, oils, fats, and greasy substances.

In an embodiment, the hydrophobic coating has a thickness of less than 500 nm, for example less than 10 nm. In particular, the hydrophobic coating may be a hydrophobic layer which has a maximum thickness of less than 500 nm or less than 100 nm, for example less than 10 nm. With such very small thicknesses of the hydrophobic coating, not only a reliable protection of the functional body may be achieved, but also a proper thermal coupling between an interior of the functional body and the immersion cooling liquid may be maintained. This may allow to combine to a high mechanical integrity and a proper thermal performance.

In an embodiment, the hydrophobic coating is configured to reduce the interactions of oxidation products of the liquid with the surface.

In an embodiment, the hydrophobic coating is configured to inhibit a chemical interaction with carboxylic acid, in particular to provide repelling forces to carboxylic acid. By repelling carboxylic acid, which may be formed by oxidation by dioxygen in an immersion cooling liquid, the hydrophobic coating may keep such carboxylic acid away from the functional body and may therefore protect the latter.

In an embodiment, the hydrophobic coating is configured to promote interaction with immersion cooling liquid, in particular to promote an attractive interaction with immersion cooling liquid. Advantageously, an attraction of fresh immersion cooling liquid by the hydrophobic coating may enhance the thermal coupling in between. This may improve the thermal performance of the electronic device. For example, single-phase immersion cooling liquids may comprise a formulation of hydrocarbons, in particular polyalphaolefins, which may be oligomerized olefins e.g. 1-decene, 1-dodecene, etc.

In an embodiment, the hydrophobic coating has antifoaming properties, in particular when hydrolyzed or detached in any kind from surface, for instance in an encapsulant. By protecting also against the formation of undesired foam, the hydrophobic coating can further extend its functionality.

In an embodiment, the hydrophobic coating is configured to be equal to or to enhance thermal interaction between the at least one functional body and immersion cooling liquid. Thus, the hydrophobic coating may ensure that thermal interaction between functional body and immersion cooling liquid is not deteriorated. In particular, said thermal interaction may be even promoted or enhanced by the hydrophobic coating.

In an embodiment, the hydrophobic coating comprises an anchor group facing the at least one functional body and a hydrophobic residue facing away from the at least one functional body. The anchor group may have the function of connecting the hydrophobic coating in a reliable way with the functional body, in particular an encapsulant of the functional body. A chemical bond may be formed between the anchor group and the encapsulant of the functional body. This may ensure a reliable connection between hydrophobic coating and the functional body even under harsh conditions. The hydrophobic residue, on the other hand, may form a non-polar free end establishing a hydrophobic property of the hydrophobic coating.

In an embodiment, the anchor group is inorganic, metallic, and/or metal-organic-based. Many alternatives are possible. For example, the anchor group may also comprise a silicon-based chemical.

In an embodiment, the hydrophobic residue comprises an organic group, for instance an alkyl group, a cyclic organic residue, and/or an aromatic organic residue. Such hydrophobic residues are appropriate for ensuring a hydrophobic property of the hydrophobic coating at an exposed side thereof. The selection which kind of hydrophobic residue is used can be made in accordance with the properties of a used immersion cooling liquid. In particular, the hydrophobic residue may form a free end of the hydrophobic coating opposing the encapsulant. The hydrophobic residue may have non-polar properties.

In an embodiment, the hydrophobic coating comprises a hydrophobic silane. A hydrophobic silane may be a particularly good choice for the hydrophobic coating, because such a selection may ensure a pronounced hydrophobic characteristic and is also compatible with the connection, for instance in a self-aligned way, with an encapsulant in form of an epoxy mold compound.

In an embodiment, a water contact angle of the hydrophobic coating is larger than 95°, in particular larger than 100°. The water contact angle may denote the angle between a liquid (in particular an aqueous solution or water) surface and a solid surface where they meet. In the present scenario, the water contact angle may quantify the wettability of the solid surface of the encapsulant by the immersion cooling liquid. The larger the contact angle, the more pronounced the hydrophobic property of the surface.

In an embodiment, the encapsulant comprises a mold compound, in particular an epoxy mold compound. In particular, such a mold compound may be used for encapsulating semiconductor dies, for instance power semiconductor dies, in a package.

When cooling such a package and/or another electronic device or functional body by immersion cooling, the hydrophobic coating of the mold compound may ensure mechanical integrity and high thermal performance of the package.

In an embodiment, the at least one functional body comprises at least one of the group consisting of a semiconductor package (for instance a semiconductor package), a semiconductor chip (for instance manufactured in silicon technology, in silicon carbide technology or in gallium nitride technology), a passive component (for instance a capacitor, an inductor or a resistor), a lead (for instance made of a metal such as copper) for electrically coupling an electronic component, and/or a coating for coating an electronic component. Other functional bodies are possible as well.

In an embodiment, the at least one functional body comprises a carrier for carrying an electronic component. In the context of the present application, the term “carrier” may particularly denote a support structure (which may be at least partially electrically conductive) which serves as a mechanical support for one or more electronic component(s) to be mounted thereon, and which may also contribute to the electric interconnection between one or more electronic component(s) and the periphery of a package. In other words, the carrier may fulfil a mechanical support function and an electric connection function. A carrier may comprise or consist of a single part, multiple parts joined via encapsulation or other package components, or a subassembly of carriers. When the carrier forms part of a leadframe, it may be or may comprise a die pad. For instance, such a carrier may be a leadframe structure (for instance made of copper), a DAB (Direct Aluminum Bonding) substrate, a DCB (Direct Copper Bonding) substrate, etc. Moreover, the carrier may also be configured as Active Metal Brazing (AMB) substrate.

In an embodiment, the at least one functional body comprises an electronic component. The electronic component may be mounted on a carrier. In the context of the present application, the term “electronic component” may in particular encompass a semiconductor chip (in particular a power semiconductor chip), an active electronic device (such as a transistor), a passive electronic device (such as a capacitance or an inductance or an ohmic resistance), a sensor (such as a microphone, a light sensor or a gas sensor), an actuator (for instance a loudspeaker), and a microelectromechanical system (MEMS).

However, in other embodiments, the electronic component may also be of different type, such as a mechatronic member, in particular a mechanical switch, etc.

In an embodiment, the at least one functional body comprises an electrically conductive coupling element for electrically coupling an electronic component, for instance with a carrier. Such an electrically conductive coupling element may be a clip, a bond wire or a bond ribbon. A clip may be a curved electrically conductive plate body accomplishing an electric connection with a high connection area to an upper main surface of a respective electronic component. Additionally or alternatively to such a clip, it is also possible to implement one or more other electrically conductive interconnect bodies in a package, for instance a bond wire and/or a bond ribbon connecting the electronic component with the carrier or connecting different pads of an electronic component.

In an embodiment, the electronic device comprises a mounting base on which the at least one functional body is mounted. The mounting base can be for example a printed circuit board (PCB) or any other laminate substrate, a Direct Copper Bonding substrate (DCB), a Direct Aluminum Bonding substrate (DAB), an Active Metal Brazing substrate (AMB), glass, a ceramic substrate such as a Low or High Temperature Cofired Ceramics (LTCC, HTCC), etc. For instance, such a mounting base can also be a leadframe structure (for instance made of copper).

In an embodiment, the mounting base comprises a further hydrophobic coating at least part of which covering at least part of an exterior surface of the mounting base.

Hence, an extra protection of the mounting base with respect to an immersion cooling liquid may be provided by said further hydrophobic coating. The whole electronic device may thus be protected. The embodiments described herein for the hydrophobic coating (in particular its chemical composition and its geometrical properties) may also apply to the further hydrophobic coating.

In an embodiment, the hydrophobic coating and the further hydrophobic coating are integrally formed. Alternatively, the hydrophobic coating and the further hydrophobic coating may be provided separately from each other. For example, hydrophobic coating of the at least one functional body and further hydrophobic coating of the mounting base may be made of the same material and may be integrally connected, for simplifying the manufacturing process. In another embodiment, hydrophobic coating of the at least one functional body on the one hand and further hydrophobic coating of the mounting base of the other hand may be made of different materials and physically separate structures. This may allow to separately and individually adjust the properties of the hydrophobic coating and of the further hydrophobic coating specifically in accordance with material of the respective underground (i.e. a respective functional body or the mounting base).

In an embodiment, part of the further hydrophobic coating covers at least part of the hydrophobic coating and/or at least part of the at least one functional body. Hence, hydrophobic coating and further hydrophobic coating may also form together a double layer or stack and/or may each extend at least partially on a functional body and partially on the mounting base for refining the hydrophobic properties.

In an embodiment, the electronic device comprises a vertical stack of one or more of said at least one functional body and/or of a mounting base on which the at least one functional body is mounted. Advantageously, a three-dimensional stack of at least three, in particular more than three, elements may be formed, said elements being constituted by one or more functional bodies and one or more mounting bases.

In an embodiment, the electronic device comprises an immersion cooling liquid in which the at least one functional body is at least partially immersed. Such immersion cooling liquid may be a dielectric liquid, optionally comprising antioxidants and/or other additives. For example, inert hydrocarbons (such as polyalphaolefins) may be used for single-phase or two-phase immersion cooling liquids. The electronic device may be subjected to immersion cooling during electric operation.

In an embodiment, the method comprises forming the hydrophobic coating by spraying or spin coating. This is a simple way of forming a hydrophobic coating in a homogeneous way on a surface, such as an exposed encapsulant surface of a functional body. Other methods for forming the hydrophobic coating are possible, for example immersing functional body and/or mounting base in a hydrophobic precursor solution.

Patterning of a hydrophobic coating (for instance by etching or photolithographically) on functional body and/or mounting base may be possible as well.

In an embodiment, the method comprises forming the hydrophobic coating by an alkyl silanol treatment. When the hydrophobic coating cures (for instance after spraying or spin coating), the hydrophobic coating may advantageously experience a self-assembly of molecules.

In an embodiment, the method comprises mounting the at least one functional body covered by the hydrophobic coating on a mounting base, and subsequently forming a further hydrophobic coating covering at least part of an exterior surface of the mounting base. Advantageously, this may protect both the functional body (thanks to its hydrophobic coating) and the mounting base (due to its further hydrophobic coating) when being subjected to an immersion cooling liquid. This holds in particular when the method comprises mounting the at least one functional body on a mounting base, and at least partially immersing the mounting base in the immersion cooling liquid.

In an embodiment, the functional body may be embodied as a package which comprises a carrier on which an electronic component is mounted. For instance, such a carrier may be a leadframe (for instance made of copper), a DAB (Direct Aluminum Bonding), DCB (Direct Copper Bonding) substrate, etc. Also at least part of the carrier may be encapsulated by the encapsulant, together with the electronic component.

In an embodiment, the package is configured as one of the group consisting of a leadframe connected power module, a Transistor Outline (TO) package, a Quad Flat No Leads Package (QFN) package, a Small Outline (SO) package, a Small Outline Transistor (SOT) package, and a Thin Small Outline Package (TSOP) package. Also packages for sensors and/or mechatronic devices are possible embodiments. Moreover, exemplary embodiments may also relate to packages functioning as nano-batteries or nano-fuel cells or other devices with chemical, mechanical, optical and/or magnetic actuators. Therefore, a package of an electronic device according to an exemplary embodiment is fully compatible with standard packaging concepts (in particular fully compatible with standard TO packaging concepts) and appears externally as a conventional package, which is highly user-convenient.

In an embodiment, the package is configured as power module, for instance molded power module such as a semiconductor power package. For instance, an exemplary embodiment of the package may be an intelligent power module (IPM). Another exemplary embodiment of the package is a dual inline package (DIP).

In an embodiment, the electronic component is configured as a power semiconductor chip. Thus, the electronic component (such as a semiconductor chip) may be used for power applications for instance in the automotive field and may for instance have at least one integrated insulated-gate bipolar transistor (IGBT) and/or at least one transistor of another type (such as a MOSFET, a JFET, etc.) and/or at least one integrated diode. Such integrated circuit elements may be made for instance in silicon technology or based on wide-bandgap semiconductors (such as silicon carbide). A semiconductor power chip may comprise one or more field effect transistors, diodes, inverter circuits, half-bridges, full-bridges, drivers, logic circuits, further devices, etc.

As substrate or wafer forming the basis of the electronic components, a semiconductor substrate, in particular a silicon substrate, may be used. Alternatively, a silicon oxide or another insulator substrate may be provided. It is also possible to implement a germanium substrate or a III-V-semiconductor material. For instance, exemplary embodiments may be implemented in GaN or SiC technology.

The above and other objects, features and advantages will become apparent from the following description and the appended claims, taken in conjunction with the accompanying drawings, in which like parts or elements are denoted by like reference numbers.

The illustration in the drawing is schematically and not to scale.

Before exemplary embodiments will be described in more detail referring to the figures, some general considerations will be summarized based on which exemplary embodiments have been developed.

Immersion cooling is emerging for example for server applications as highly efficient type of cooling versus air cooling. However, highly complex material interaction may occur between an immersion cooling liquid and constituents of an electronic device, such as metal pads, adhesives, flux, solder or sinter, etc.

For reasons of efficiency, a long lifetime and re-use of immersion cooling liquid may be desired. However, a long-term storage of immersion cooling liquid may result in degradation, in particular involving oxidation. In many cases, relatively inert hydrocarbons may be used as single-phase immersion cooling liquids. However, this may involve the problem that hydrocarbon C-C and/or C-H bonds can form radicals caused by immersion cooling conditions, which can result for example in the creation of carboxylic acids.

Challenging conditions may occur during immersion cooling. In particular, immersion cooling may be done at temperatures of for example 50-60° C., and hot spots can involve even higher temperatures. Due to the use of open tanks, issues with oxygen may occur. Long storage times may be involved when using immersion cooling liquids. Metals (for example copper) of electronic devices may unintentionally function as oxidation catalysts. Liquid pumping may involve additional challenges.

Conventional hydrocarbons may contain antioxidants to inhibit oxidation and/or radical chain reactions. However, antioxidants may be consumed over prolonged storage.

According to an exemplary embodiment, an electronic device may be provided which is appropriate to be used for immersion cooling. For example, such an electronic device may comprise a power semiconductor chip mounted on a printed circuit board, many other applications are possible. Advantageously, one or more encapsulated functional bodies of the electronic device may be at least partially covered at an exterior surface by a hydrophobic coating as device protection against degradation products of immersion cooling liquid coming into a direct physical contact with the electronic device during immersion cooling for heat dissipation during operation. A functional body of the electronic device may have an exterior surface or interface defined by an encapsulant, such as an epoxy mold compound or an organic laminate. By coating such an exterior surface of the functional body, in particular an encapsulant thereof, with a hydrophobic coating, compatibility of the electronic device with immersion cooling- and in particular with an immersion cooling liquid used for immersion cooling-may be significantly improved.

Beneficially, this may reduce the danger of an undesired impact of immersion cooling liquid on the structural and/or functional integrity of the functional body of the electronic device. For example, an undesired interaction between immersion cooling liquid and electronic device, which may be suppressed or eliminated according to exemplary embodiments, may be the unintentional creation of free radicals in an interface region between immersion cooling liquid and electronic device. Such free radicals may be chemically aggressive and may deteriorate electronic device integrity by triggering radical chain reactions. As a result, the provision of a hydrophobic coating on an encapsulant of a functional body of an electronic device may improve device reliability during electronic operation while the electronic device is being efficiently cooled by immersion cooling liquid.

Advantageously, packages and other electronic devices according to exemplary embodiments may be specifically adapted or even optimized regarding their reliability or thermal performance for immersion cooling applications. In particular, the provision of a hydrophobic coating on at least part of an encapsulated surface of a functional body of an electronic device may result in an advantageous surface modification for immersion cooling. Preferably, such a surface modification in the form of a hydrophobic coating may be accomplished by the provision of an ultra-thin hydrophobic organic layer (for instance having a thickness of a few molecule layers). A thickness of the hydrophobic coating may be below 1 μm, for example below 500 nm, preferably below 100 nm, specifically below 10 nm. Advantageously, such a very thin hydrophobic coating may avoid an undesired thermal insulation by the hydrophobic coating itself, which would deteriorate the cooling performance. With such a thin-film hydrophobic coating, reliable protection of an encapsulated surface of a functional body may be synergistically combined with a high thermal performance. Beneficially, this may also lead to a long lifetime by package surface protection through preventing and/or delaying unwanted side reactions. In contrast to conventional approaches, electronic devices such as packages may be improved regarding reliability and/or thermal performance for immersion cooling applications.

Hence, an exemplary embodiment may provide an electronic device with a hydrophobic coating or surface. Advantageously, this may be achieved for instance by an alkyl silanol treatment, in particular on single components and/or in particular on an epoxy mold compound.

Advantageously, a hydrophobic coating may be configured as one or more protective layers. Such a hydrophobic coating may be applied on electronic devices, functional bodies or single components such as metal interconnects, passive components, semiconductor packages including mold compound and material interfaces for example solder, leads, plastics, ceramics, etc. Preferably, the protective layer provides a hydrophobic surface on said electronic device, functional body or single components. In particular, the hydrophobic coating embodied as protective layer may be achieved via an alkyl silanol treatment. In yet another embodiment, one or more additional protective layers in the form of a hydrophobic coating may be applied on a mounting base (for instance a mounting board, such as a printed circuit boards, PCB). For example, this may be done after SMD (surface mounted device) mounting (for instance soldering) of one or more electronic components or other type of functional bodies on the mounting base.

Beneficially, the thermal performance of the electronic device, functional body or single component(s) may be improved thanks to the hydrophobic coating which may be embodied as protective layer(s).

In a preferred embodiment, a surface treatment of an at least partially encapsulated functional body may be carried out for forming one or more protective layer(s) to achieve a hydrophobic surface by alkyl silanol treatment.

Exemplary embodiments have advantages: The provision of a hydrophobic coating of an encapsulant or part thereof of a functional body may lead to a decreased interaction of the hydrophobic surface (in particular package surface) with for example carboxylic acids. This may result in an improved lifetime of the electronic device. Advantageously, exemplary embodiments may also promote an increased interaction of fresh immersion cooling liquids with a surface of a functional body, in particular of a package surface.

Beneficially, an improved thermal performance may be achieved as well. Moreover, silanol (for instance in the form of unreacted residues or dissolved in a liquid) may have antifoaming properties. Also this may have a positive impact on the thermal performance.

In a preferred embodiment, a protective layer embodied as hydrophobic coating may be applied not only on an encapsulant of a functional body. It may also be possible to provide one or more additional protective layers embodied as additional hydrophobic coating which may be applied on a mounting base for functional bodies, such as a PCB, after SMD soldering of one or more electronic components as functional bodies.

Silane may be an appropriate material for the hydrophobic coating. A water contact angle of hydrophobic silanes may be larger than 100°. For comparison, a water contact angle of epoxy may be less than 90°. Advantageously, a silane/silanol system may also be used as adhesion promoter for promoting adhesion of an epoxy mold compound.

Advantageously, using hydrophobic silanes on a mold compound surface may significantly improve the suitability of an electronic device for immersion cooling. In particular, such a hydrophobic coating may be applied in a simple way for example by spraying or spin coating. Descriptively speaking, a material of the hydrophobic coating may operate as self-assembly molecules.

In an embodiment, sequential coating with multiple hydrophobic layers may be carried out for higher robustness. For example, a hydrophobic coating may be formed on a package first. Additionally, hydrophobic coating may also be formed on system level (for example the on a board assembly) to further increase robustness. Preferably, a hydrophobic coating may be embodied as a protection layer with organic residues. An anchor group can be inorganic or element-based, metal-based, organic-based, etc. This may be accomplished for example by the use of a silicone, an aluminate, a phosphate, etc.

Hydrophobic organic residues may comprise for example one or more alkyl groups. For example, said organic residues may comprise cyclic organic residues and/or aromatic hydrocarbons. This may enhance polarity characteristics. It may also be possible that said organic residues comprise saturated alkyl groups. The selection of organic residues may allow to choose the hydrophobic coating to a specific immersion cooling liquid.

Exemplary embodiments may be applied to very different package types, in particular for molded discrete packages.

Exemplary applications of exemplary embodiments are for example high-end IT (information technology) applications, data centers, the artificial intelligence devices, quantum computers, server applications and/or power conversion applications. More generally, electronic devices according to exemplary embodiments may be applied in particular to any kind of application in which high power densities are involved.

Exemplary embodiments may provide a protecting hydrophobic coating as device protection on an encapsulant surface of a functional body of an electronic device.

Advantageously, this may provide an intrinsic protection by inhibiting or preventing a direct interaction between critical device surfaces and immersion cooling liquid. In particular, at least part of the hydrophobic coating may be applied on at least part of an epoxy mold compound, as an example of an encapsulant. In particular, it may also be possible to vertically stack functional bodies for forming a three dimensionally stacked electronic device.

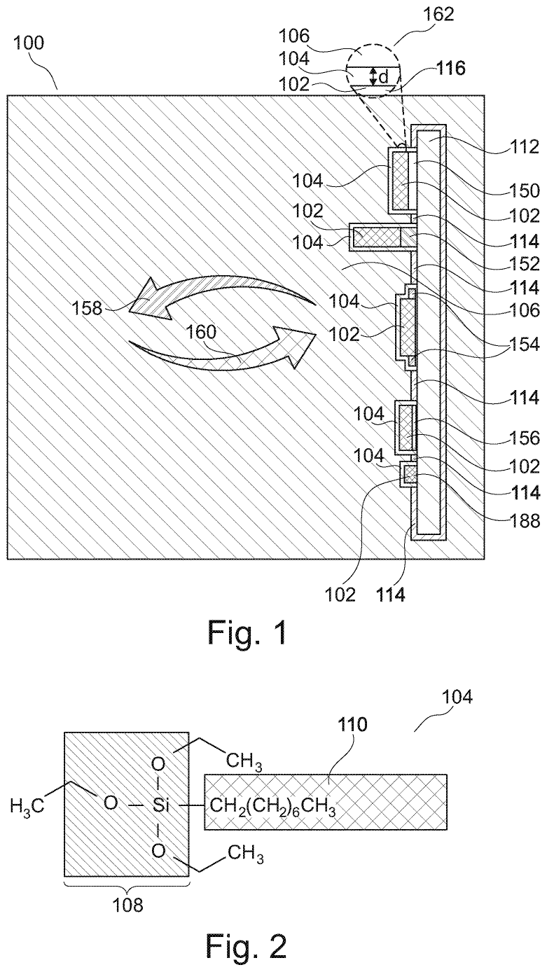

FIG. 1 illustrates an electronic device 100 according to an exemplary embodiment.

The electronic device 100 is illustrated in FIG. 1 during immersion cooling, in which the electronic device 100 or part thereof is immersed in an immersion cooling liquid 106. Hence, the arrangement of FIG. 1 comprises immersion cooling liquid 106 in which a plurality of functional bodies 102 and a carrying mounting base 112 are immersed. For instance, the electronic device 100 may be arranged in a container (not shown) in which also the immersion cooling liquid 106 is contained. For enhancing thermal exchange between the immersed cooling liquid 106 and the hardware elements of the electronic device 100, a pump (not shown) may be provided for pumping or circulating the immersion cooling liquid 106 to flow around the hardware elements of the electronic device 100. Advantageously, the immersion cooling liquid 106 may be a dielectric liquid. By being electrically non-conductive, the immersion cooling liquid 106 will not have an undesired impact on current flow within the electronic device 100. For instance, the immersion cooling liquid 106 may be a single-phase or two-phase dielectric fluid.

Optionally, antioxidants may be included in the immersion cooling liquid 106. Such antioxidants may also function to capture radicals.

The electronic device 100 according to FIG. 1 comprises a mounting base 112. In the shown embodiment, the mounting base 112 is a plate-shaped electronic board on which a plurality of functional bodies 102 are surface mounted. More specifically, mounting base 112 of FIG. 1 may be a printed circuit board (PCB). The mounting base 112 may have a mechanical support function for mechanically supporting the functional bodies 12 and may have an electric connection function for interconnecting the functional bodies 102 with each other by wiring and pads.

As shown in FIG. 1, a plurality of functional bodies 102 are mounted on the mounting base 112. Generally, any of the functional bodies 102 may comprise or may be for example a semiconductor package, an electronic component, a semiconductor chip, a passive component, etc. For example, one functional body 102 may be a semiconductor package mounted on the mounting base 112 via a thermal interface material 150 (TIM). A further functional body 112 may be a passive component, such as a capacitor, mounted on the mounting base 112 via a sealing 152. Another functional body 112 may be a semiconductor package mounted on the mounting base 112 via an electrically conductive connection medium 154, such as a solder and/or flux. Still another functional body 112 may be an electronic component mounted on the mounting base 112 via an adhesive 156. Yet another functional body 112 may be arranged on the mounting base 112 as a cable (for example a quad small form factor, QSFP, pluggable). Any desired combination of one or more functional bodies 102 may be foreseen.

As indicated schematically in FIG. 1, various phenomena may occur during immersion cooling. In particular, leaching into the immersion cooling liquid 106 may occur, as indicated schematically by reference sign 168. Moreover, there may be an influence of contaminants of the immersion cooling liquid 106, as indicated by reference sign 160.

A detail 162 of FIG. 1 shows an interface between an exemplary functional body 102 and the immersion cooling liquid 106. Said functional body 102 may be partially delimited by an encapsulant 116. In other words, part of an exterior surface of said functional body 102 may be defined by encapsulant 116, which may be an epoxy mold compound. When in direct physical contact with each other, there may be an undesired interaction between material of encapsulant 116 and immersing cooling liquid 106, for instance the formation of free radicals. Such phenomena may negatively impact performance and reliability of the electronic device 100 and/or the immersion cooling liquid 106. In order to avoid an undesired chemical interaction between the epoxy mold compound of the encapsulant 116 on the one hand and the immersion cooling liquid 106 on the other hand, a hydrophobic coating 104 may be applied to cover an exterior surface of the encapsulated functional body 102. More specifically and as shown in detail 162, hydrophobic coating 104 may be arranged on an exterior surface of encapsulant 116 or part thereof. It may also be possible to cover other surface portions of the respective functional body 102 with hydrophobic coating 104.

Advantageously, the hydrophobic coating 104 has a very small thickness d. For instance, thickness d may be less than 500 nm, or even less than 10 nm. Beneficially, such a small thickness d reliably protects the encapsulant 114 and the functional body 102 as a whole with respect to the immersing cooling liquid 106, while simultaneously being sufficiently thin so that the hydrophobic coating 104 does not lead to a noteworthy deterioration of the thermal coupling between an interior of the functional body 102 and the immersing cooling liquid 106.

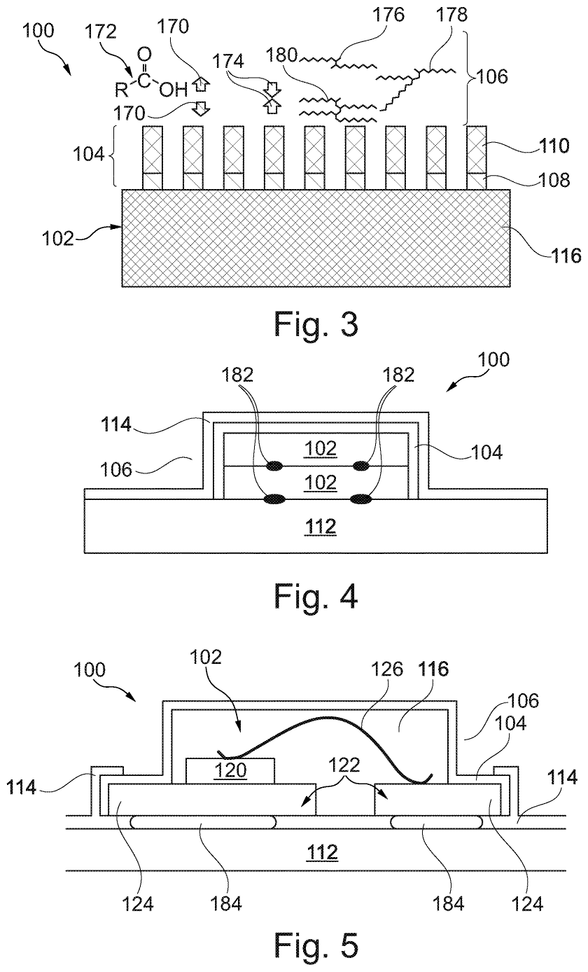

It may be preferred that a water contact angle of the hydrophobic coating 104 is larger than 100°. Thus, the hydrophobic coating 104 may show pronounced hydrophobic properties. Advantageously, it may be for instance possible to form the hydrophobic coating 104 from a material capable of inhibiting a chemical interaction with carboxylic acid. More specifically, the hydrophobic coating 104 may be configured to provide repelling forces to carboxylic acid. Moreover, the hydrophobic coating 104 may be configured to promote interaction with immersion cooling liquid 106. Advantageously, it may be possible that the hydrophobic coating 104 is configured to promote an attractive interaction with the immersion cooling liquid 106. It may also be possible that the hydrophobic coating 104 is configured to have antifoaming properties. At the same time, the hydrophobic coating 104 may be configured to enhance thermal interaction between the functional body 102 and the immersion cooling liquid 106. In a preferred embodiment, the hydrophobic coating 104 comprises a hydrophobic silane. Details about an advantageous configuration of a hydrophobic coating 104 can be taken for instance from FIG. 2 and FIG. 3.

As already mentioned, the various functional bodies 102 are surface mounted on the mounting base 112. Advantageously, a further or additional hydrophobic coating 114 may at least partially cover an exterior surface of the mounting base 112. For instance, hydrophobic coating 104 may cover at least mold compound-type encapsulant 116 of functional bodies 102, whereas additional hydrophobic coating 114 may cover organic laminate-type encapsulant (for instance epoxy resin or prepreg) of mounting base 112.

During a manufacturing process, it may be for instance possible to mount the various functional bodies 102 already covered by the hydrophobic coating 104 on the mounting base 112, and subsequently forming the further hydrophobic coating 114 to cover part of or an entire exterior surface of the mounting base 112. The additional hydrophobic coating 114 may be embodied as the hydrophobic coating 104 or may have different properties.

The hydrophobic coating 104 and the further hydrophobic coating 114 may be separate structures or may be integrally formed. When being integrally formed, hydrophobic coatings 104, 114 may be applied together and thus with particularly low effort. When being provided as separate structures, the specific properties of hydrophobic coatings 104, 114 may be adjusted individually so as to comply specifically with the requirements of the underlying functional body 102 or mounting base 112. In another embodiment, additional hydrophobic coating 114 may also be omitted.

During a manufacturing process, each of the hydrophobic coating 104 and the further hydrophobic coating 114 may be formed for example by spraying or spin coating. For instance, any of the hydrophobic coating 104 and the further hydrophobic coating 114 may be manufactured by an alkyl silanol treatment of the respective underlying surface.

FIG. 2 illustrates a hydrophobic coating 104 of a functional body 102 of an electronic device 100 according to an exemplary embodiment. Further hydrophobic coating 114 may also be embodied as hydrophobic coating 104 is as described referring to FIG. 2, or differently.

As shown, the hydrophobic coating 104 comprises an anchor group 108. When the hydrophobic coating 104 is formed on an encapsulant 116 of a functional component 102, the anchor group 108 faces the functional body 102. For example, the anchor group 108 may be inorganic, metallic, and/or metal-organic-based. The anchor group 108 may also comprise a SiO₃ group.

Furthermore, the hydrophobic coating 104 may comprise a hydrophobic residue 110 facing away from the functional body 102. For example, said hydrophobic residue 110 may comprise an organic group. For instance, such an organic group may comprise an alkyl group, a cyclic organic residue, and/or an aromatic organic residue. At its free end, the hydrophobic residue 110 may have a non-polar group.

The hydrophobic coating 104 may also comprise one or more additional chemical groups, such as CH₃ groups.

For example, the hydrophobic coating 104 may comprise n-octyltriethoxysilane.

For instance, the hydrophobic coating 104 may be prepared by hydrolyzation of silane to silanol. For example, a hydrolyzed precursor of the hydrophobic coating 104 may be sprayed on an encapsulant surface, for instance in a medium such as isopropanol and water. After evaporation of said medium or part thereof, the hydrophobic coating 104 remains on the surface to be protected. Upon spraying, a self-assembly may occur during curing leading to an anchored connection of the hydrophobic coating 104 on the encapsulant 116 and/or another surface of the functional body 102 or a mounting base 112. For example, a water contact angle of hydrophobic silanes may be larger than 100°. For comparison, a water contact angle of epoxy may be below 90°.

FIG. 3 illustrates an electronic device 100 according to another exemplary embodiment.

As shown, an encapsulant 116 which may be embodied as an epoxy mold compound may be covered by a hydrophobic coating 104 with its anchor group 108 connected to encapsulant 116 and its hydrophobic residue 110 at a free end being exposed to immersion cooling liquid 106.

As indicated by reference sign 170, repelling forces may be created by the hydrophobic coating 104 with respect to carboxylic acids 172. As indicated by reference sign 174, an attracting interaction between fresh immersion cooling liquid 106 (for instance comprising dimers 176, trimers 178 and tetramers 180) and the hydrophobic coating 106 may be created. Thus, a protecting function of the hydrophobic coating 104 against carboxylic acids 172 and other phenomena caused by free radicals may be combined with a desired attracting interaction between polymers of the immersion cooling liquid 106 and the functional body 102.

FIG. 4 illustrates an electronic device 100 according to another exemplary embodiment.

The electronic device 100 according to FIG. 4 comprises a mounting base 112 on which a first functional body 102 is surface mounted. A second functional body 102 is mounted on top of the first functional body 102. The vertical stack of mounting base 112 and functional bodies 102, 102 may be mechanically and electrically coupled, see connections 182 between the stacks constituents. Such connections 182 may for instance be solder connections, sinter connections or connections in form of electrically conductive glue. Said connections 182 may connect for instance exposed pads on facing connection surfaces of the stacked constituents. Thus, the embodiment of FIG. 4 shows a vertical stack of vertically stacked functional bodies 102, 102 and mounting base 112 on which the vertically stacked functional bodies 102 are mounted.

As shown as well, an exposed surface of the functional bodies 102 is covered by a hydrophobic coating 104. Moreover, an exposed surface of the mounting base 112 as well as an exposed surface of the hydrophobic coating 104 may be covered by further hydrophobic coating 114. The obtained stack is thus properly protected in a scenario in which the electronic device 100 according to FIG. 4 is subjected to immersion cooling in an immersion cooling liquid 106.

FIG. 5 illustrates an electronic device 100 according to another exemplary embodiment.

The illustrated package-type electronic device 100 comprises a carrier 122, which may for instance be a leadframe structure, for instance made of copper. An electronic component 120 may be mounted on the carrier 122. For instance, the electronic component 120 may be a semiconductor die, for instance manufactured in silicon technology or silicon carbide technology. For example, the electronic component 120 may be a semiconductor power chip. An electrically conductive coupling element 126, for example a bond wire (or alternatively a clip), may electrically couple the electronic component 120 with the carrier 122. An encapsulant 116, for example an epoxy mold compound, may encapsulate the electronic component 120, the electrically conductive coupling element 126, and part of the carrier 120. The encapsulant 116 and part of the exposed surfaces of carrier 122 forming leads 124 are covered by hydrophobic coating 104. A remaining exposed surface of the carrier 124 may be electrically connected with a mounting base 112 under the functional body 102. This electric connection may be accomplished by an electrically conductive connection medium 184, such as a solder. At least part of an exposed surface of the mounting base 112 and optionally at least part of a surface of hydrophobic coating 104 may be covered by a further hydrophobic coating 114.

By taking this measure, the electronic device 100 of FIG. 5 may be made fit for utilization in immersion cooling during which the electronic device 100 is immersed in immersion cooling liquid 106.

It should be noted that the term “comprising” does not exclude other elements or features and the “a” or “an” does not exclude a plurality. Also elements described in association with different embodiments may be combined. It should also be noted that reference signs shall not be construed as limiting the scope of the claims.

Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. An electronic device for immersion cooling, comprising:
at least one functional body being at least partially delimited by an encapsulant; and
a hydrophobic coating covering at least part of an exterior surface of the at least one functional body.

2. The electronic device according to claim 1, wherein the hydrophobic coating has a thickness of less than 500 nm, for example less than 10 nm.

3. The electronic device according to claim 1, wherein the hydrophobic coating is configured to reduce interactions of oxidation products of an immersion liquid with the surface.

4. The electronic device according to claim 1, wherein the hydrophobic coating is configured to inhibit a chemical interaction with carboxylic acid, in particular to provide repelling forces to carboxylic acid.

5. The electronic device according to claim 1, wherein the hydrophobic coating is configured to promote interaction with immersion cooling liquid, in particular to promote an attractive interaction with immersion cooling liquid.

6. The electronic device according to claim 1, wherein the hydrophobic coating has antifoaming properties, in particular when hydrolyzed or detached in any kind from surface, for instance in an encapsulant.

7. The electronic device according to claim 1, wherein the hydrophobic coating is configured to be equal to or to enhance thermal interaction between the at least one functional body and immersion cooling liquid.

8. The electronic device according to claim 1, wherein the hydrophobic coating comprises an anchor group facing the at least one functional body and a hydrophobic residue facing away from the at least one functional body.

9. The electronic device according to claim 8, comprising at least one of the following features:
wherein the anchor group is inorganic, metallic, and/or metal-organic-based;
wherein the hydrophobic residue comprises an organic group, for instance an alkyl group, a cyclic organic residue, and/or an aromatic organic residue.

10. The electronic device according to claim 1, wherein the hydrophobic coating comprises a hydrophobic silane.

11. The electronic device according to claim 1, wherein a water contact angle of the hydrophobic coating is larger than 95°, in particular larger than 100°.

12. The electronic device according to claim 1, wherein the encapsulant comprises a mold compound, in particular an epoxy mold compound.

13. The electronic device according to claim 1, wherein the at least one functional body comprises at least one of the group consisting of a semiconductor package, an electronic component, a semiconductor chip, a passive component, a carrier for carrying an electronic component, a lead for electrically coupling an electronic component, a coating for coating an electronic component, and an electrically conductive coupling element for electrically coupling an electronic component.

14. The electronic device according to claim 1, comprising a mounting base on which the at least one functional body is mounted, and in particular comprising a further hydrophobic coating at least part of which covering at least part of an exterior surface of the mounting base.

15. The electronic device according to claim 14, comprising at least one of the following features:
wherein the hydrophobic coating and the further hydrophobic coating are integrally formed or are provided separately from each other;
wherein part of the further hydrophobic coating covers at least part of the hydrophobic coating and/or at least part of the at least one functional body.

16. The electronic device according to claim 1, comprising at least one of the following features:
comprising a vertical stack of one or more of said at least one functional body and/or of a mounting base on which the at least one functional body is mounted;
comprising an immersion cooling liquid in which the at least one functional body is at least partially immersed.

17. A method of manufacturing an electronic device for immersion cooling, the method comprising:
providing at least one functional body being at least partially delimited by an encapsulant; and
covering at least part of an exterior surface of the at least one functional body by a hydrophobic coating.

18. The method according to claim 17, comprising at least one of the following features:
wherein the method comprises forming the hydrophobic coating by spraying or spin coating;
wherein the method comprises forming the hydrophobic coating by an alkyl silanol treatment;
wherein the method comprises mounting the at least one functional body covered by the hydrophobic coating on a mounting base, and subsequently forming a further hydrophobic coating covering at least part of an exterior surface of the mounting base.

19. A method, comprising:
providing an electronic device according to claim 1; and
at least partially immersing the at least one functional body covered by the hydrophobic coating in an immersion cooling liquid.

20. The method according to claim 19, the method comprising mounting the at least one functional body on a mounting base, and at least partially immersing the mounting base in the immersion cooling liquid.
